(19) United States
(12) Patent Application Publication
(10) Pub. No.: US 2024/0317084 A1
(43) Pub. Date: Sep. 26, 2024

(54) DIRECT CURRENT FAST CHARGE MONITORING AND CONTROL

(71) Applicant: FORD GLOBAL TECHNOLOGIES, LLC, DEARBORN, MI (US)

(72) Inventors: Suriyaprakash Janarthanam, Canton, MI (US); Benjamin A. Tabatowski-Bush, Ann Arbor, MI (US)

(21) Appl. No.: 18/186,382

(22) Filed: Mar. 20, 2023

(51) Int. Cl. B60L 53/20; H02J 7/00

(52) U.S. Cl. CPC B60L 53/20; H02J 7/0047; H02J 7/00712; B60L 2210/10

(57) ABSTRACT

A controller, during DC fast charge of a traction battery, commands a DC charge current to have a magnitude less than a predefined value and responsive to magnitudes of resulting voltage drop data for a fast charge contactor connected between a charge port and main contactor being less than a first threshold value, commands the DC charge current to have a magnitude at a target high value.

### TECHNICAL FIELD

This disclosure relates to automotive power systems.

### BACKGROUND

An automotive vehicle may include an energy storage device, such as a battery. This energy may be made available to electrical and electronic components of the vehicle and outside the vehicle.

### SUMMARY

A vehicle system includes a controller that, during DC fast charge of a traction battery, commands a DC charge current to have a magnitude less than a predefined value and responsive to magnitudes of resulting voltage drop data for a fast charge contactor connected between a charge port and main contactor being less than a first threshold value, commands the DC charge current to have a magnitude at a target high value and responsive to magnitudes of resulting voltage drop data for the fast charge contactor being greater than a second threshold value, discontinues the DC fast charge.

A method includes, during DC fast charge of a traction battery, commanding DC charge current to have a magnitude less than a predefined value and responsive to magnitudes of resulting voltage drop data for a fast charge contactor connected between a charge port and main contactor being less than a first threshold value, commanding the DC charge current to a target high value and responsive to magnitudes of resulting voltage drop data for the fast charge contactor being greater than a second threshold value, discontinue the DC fast charge.

A vehicle includes a power system having a traction battery, an electric machine, a main contactor connected between the traction battery and electric machine, a charge port, and a fast charge contactor connected between the main contactor and charge port. The vehicle also includes a controller that, responsive to magnitudes of voltage drop data for the fast charge contactor being greater than a first predefined value, commands the DC fast charge contactor closed, commands a DC charge current to have a magnitude less than a second predefined value, and responsive to voltage drop data for the fast charge contactor resulting from the magnitude less than the second predefined value being less than a first threshold value, commands the DC charge current to have a magnitude at a target high value.

### BRIEF DESCRIPTION OF THE DRAWINGS

FIG. 1 is a schematic diagram of a vehicle.

FIG. 2 is a schematic diagram of a voltage sensor of FIG. 1.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

In certain vehicles, the power electronics system can serve as the interface between the traction battery and electric drivetrain, converting high-voltage direct current (DC) stored in the traction battery into low-voltage alternating current (AC) required by the electric motor. This conversion process, in some arrangements, is performed by the power inverter, which is responsible for controlling the flow of current between the traction battery and motor, and for adjusting the voltage and frequency of the AC power supplied to the motor to achieve the desired level of torque and speed.

Another component of some power electronics system is the DC/DC converter, which is used to control voltage of the high-voltage DC power stored in the traction battery to a lower level that is suitable for operating the various electrical components in the vehicle, such as the lights and infotainment system. The DC/DC converter, in certain topologies, can also serve as a battery charger, converting the AC power from a charging station into the high-voltage DC power required by the traction battery.

In may be beneficial to design the power electronics system to be efficient to reduce energy losses and maximize vehicle range. System efficiency can be influenced by several factors, including the power electronics component quality, the thermal management of the system, and the control algorithms used to control the flow of power between the traction battery and motor.

Fast charging a high voltage battery pack in an electric vehicle using DC can be referred to as DC fast charge. During this process, a high direct current at a high voltage is used to directly charge the high voltage battery pack quickly. Due to this higher current and higher voltage, contactors that are used to connect/disconnect the high voltage battery with the charging system undergo stress, which may affect the durable life of the contactors.

It may sometimes be useful to monitor the health of these contactors so that appropriate service actions can be initiated (e.g., the contactors may be replaced). Certain contactor life measurement systems count the number of such closing/opening operations and notify the vehicle users about how many closing/opening events have occurred and how many yet remain before service may be required.

The strategies contemplated herein do not count the number of such closing/opening events. Instead, they may monitor the health of the contactors by measuring voltage drop thereacross and potentially taking appropriate action. In one example, voltage drop is monitored as a corresponding contactor is opened and closed, and observed/tracked. When the voltage drop reaches a certain threshold, a controller can send a notification for battery service and/or take further action as described below.

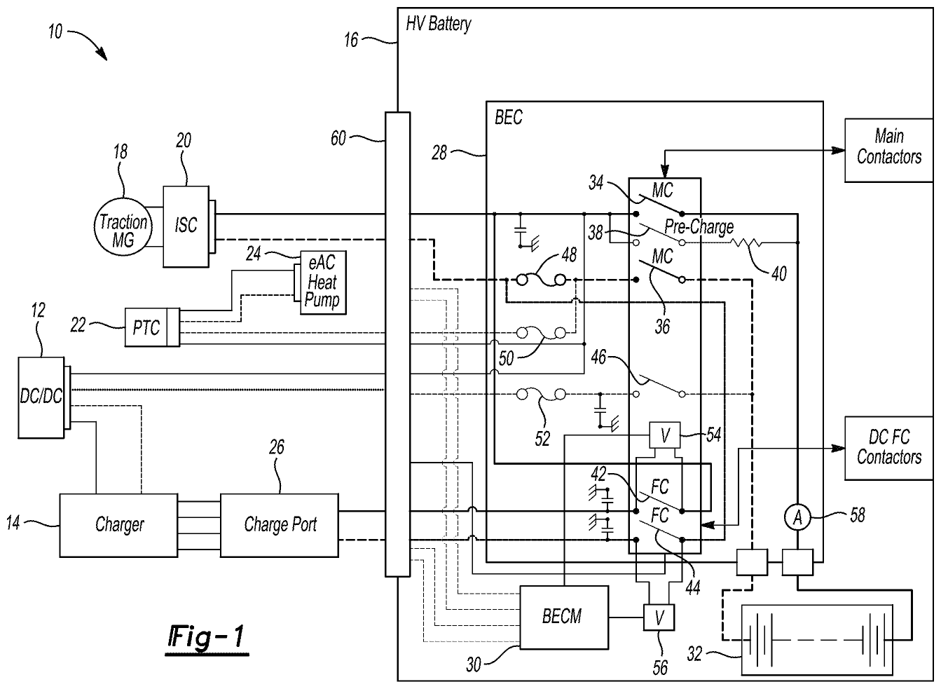

Referring to FIG. 1, a vehicle 10 includes a DC/DC converter 12, a charger 14, a traction battery system 16, a traction motor/generator 18, an inverter system controller 20, a positive temperature coefficient module 22, an electric air conditioner 24, and a charge port 26.

The charger 14 is connected with the DC/DC converter 12. And, the charge port 26 is connected with the charger 14 and the traction battery system 16 to facilitate charging. AC charging of the traction battery system 16 is facilitated via the DC/DC converter 12 and charger 14. DC charging of the traction battery system 16 bypasses the DC/DC converter 12 and charger 14.

The traction battery system 16 can be connected with the DC/DC converter 12, the inverter system controller 20, and the charger port 26 such that such AC power received from the charge port 26, and via the DC/DC converter 12 and charger 14, can be stored by the traction battery system 16, DC power received from the charge port 26 can be stored by the traction battery system 16, and power stored by the traction battery system 16 can be provided to the inverter system controller 20 for consumption by the traction motor/generator 18 while operating in motor mode. The traction battery system 16 can be further connected with the inverter system controller 20 such that power received from the traction motor/generator 18, while operating in generator mode, can be stored by the traction battery system 16.

The positive temperature coefficient module 22 is arranged to monitor the traction battery system 16 and operate the electric air conditioner 24 accordingly for the purpose of maintaining a temperature of the traction battery system 16 within some desired range.

The traction battery system 16 includes circuitry 28, a battery control module 30, and a traction battery 32. The circuitry 28 includes main contactors 34, 36, pre-charge contactor 38, pre-charge resistor 40, DC fast charge contactors 42, 44, DC/DC contactor 46, fuses 48, 50, 52, voltage sensors 54, 56, and current sensor 58. The main contactors 34, 36 are connected between the inverter system controller 20 and traction battery 32. The pre-charge contactor 38 and resistor 40 are connected in series, and they are collectively in parallel with the main contactor 34. The DC fast charge contactors 42, 44 are connected between the charge port 26 and main contactors 34, 36, respectively such that to connect the charge port 26 with the traction battery 32, the main contactors 34, 36 and DC fast charge contactors 42, 44 need to be closed. The DC contactor 46 is connected between the DC/DC converter 12 and traction battery 32.

The fuse 48 is connected between the inverter system controller 20 and the main contactor 36, the fuse 50 is connected between the positive temperature coefficient module 22 and the main contactor 34, and the fuse 52 is connected between the DC/DC converter 12 and the DC contactor 46. Current exceeding rated levels may cause the corresponding fuse to activate.

The voltage sensor 54 is connected across the fast charge contactor 42, the voltage sensor 56 is connected across the fast charge contactor 44, and the current sensor 58 is connected between the traction battery 32 and main contactor 34.

The traction battery system 16 further includes an interface 60 that is in communication with the battery control module 30 and the various connections between the traction battery system 16 and other components such that the battery control module 30 is in communication with/can exert control over the components outside the traction battery system 16. The battery control module 30 is further in communication with/can exert control over the voltage sensors 54, 56.

To fast charge the traction battery 32, the battery control module 30 may close the pre-charge contactor 38, the main contactor 36, and the fast charge contactors 42, 44. The battery control module 30 may then close the main contactor 34 and open the pre-charge contactor 38.

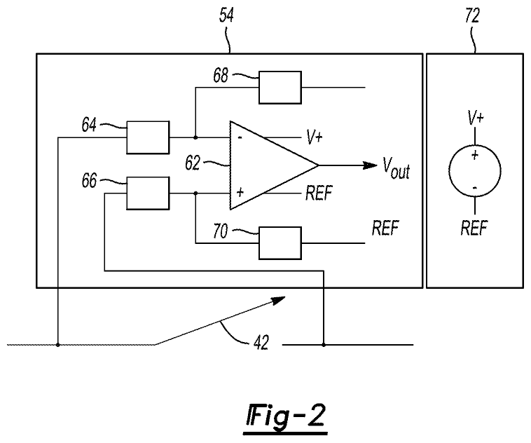

Referring to FIG. 2, the voltage sensor 54 includes operational amplifier 62, and resistors 64, 66, 68, 70. And the voltage sensor 54 is associated with power source 72. The negative port of the operational amplifier 62 is connected with one side of the DC fast charge contactor 42 via the resistor 64, and with Vout via the resistor 68. The positive port of the operational amplifier 62 is connected with the other side of the DC fast charge contactor 42 via the resistor 66, and with the power source 72 via the resistor 70.

The details on how to carry out the monitoring of the fast charge contactors 42, 44 using the differential amplifier of FIG. 2 in concert with the battery control module 20 are explained below. Broadly, the differential amplifier circuitry may be used across any contactor for monitoring as desired (e.g., used across main contactors 34, 36).

Starting with the fast charge contactors 42, 44 being open (e.g., the fast charge contactors 42, 44 may be commanded open), when it is decided to DC fast charge the traction battery 32, the voltage sensor 54 is used to assess the voltage across the fast charge contactor 42. If the voltage across it is, in this example, less that 5V, it is concluded that the fast charge contactor 42 is welded and the process is stopped. If the voltage across it is greater than 5V, it is concluded that the fast charge contactor 42 is not welded, and the process to DC fast charge the traction battery 32 is continued. The next step is to optionally assess the status of the fast charge contactor 44 using the voltage sensor 56. If the voltage across it is, in this example, less than 5V, it is concluded that the fast charge contactor 44 is welded and the process is stopped. If both the fast charge contactors 42, 44 are not welded (via the above described checks), the process to DC fast charge the traction battery 32 is continued.

The next step is to close the fast charge contactor 44 and send a message to corresponding electric vehicle supply equipment (EVSE) connected to the chare port 26 from the battery control module 30 using a standard communication process (e.g., J1772 charge port connector pilot wire communication, etc.). A command is sent to the EVSE to establish a set-point voltage that matches the battery pack voltage. After waiting for a predefined period of time to permit the EVSE power supply to adjust its output voltage, the voltage sensor 54 is used to measure the voltage across the fast charge contactor 42. If the voltage is, in this example, less than 5V (or 2V if stricter criteria are desired), the fast charge contactor 42 is closed as low voltage thereacross has been confirmed at time of closure.

The differential amplifier circuitry of the example voltage sensor 54 (and voltage sensor 56) uses the operational amplifier 62 with the floating, isolated power supply 72 that provides a V+ voltage and a reference voltage according to the needs of the operational amplifier 62 as called out in its data sheet. The voltage sensor 54 can thus have a reference voltage that is near in voltage to the source applied to the given contactor. For example, the reference voltage of the power source 72 may be connected to the top of the uninterrupted cell string of the traction battery 32. Then, the V+ node will be higher than the pack voltage by the value of the power source 72.

To monitor for degradation, a baseline for a specific contactor is first established. To monitor the fast charge contactor 42 for example, baseline output is obtained from the voltage sensor 54 at a time when the pack current is known to be low, for example below 20 A. This can be done during DC fast charging by commanding the DC fast charge current to be less than 20 A. This data can be stored in memory of the battery control module 30. This voltage data should be close to zero volts, and a flag can be set if the data is not close to zero. The data would only be indicative of a high voltage drop if circuitry of the battery control module 30 is not working properly, since the actual voltage drop across the fast charge contactor 42 at a relatively low pack current should be about zero volts.

The next step is to apply a known high current across the fast charger contactor 42. The battery control module 30 controls DC fast charge operations, so it is able to pulse the current to a high value approaching the high output level from the EVSE (e.g., 500 A). At this time, with the DC fast charge current pulsed high, the maximum voltage drop is expected to be across the fast charge contactor 42, as measured by the voltage sensor 54. A threshold is established, which is calculated by the current value (in this example, 500 A) multiplied by the maximum properly operating contactor resistance (e.g., 100 microohms), yielding 50 millivolts. Some margin can be added for robustness and the threshold set to, for example, 1V. If the fast charge contactor 43 is in indeed degraded, the voltage as measured by the voltage sensor 54 will be higher. For example, a contactor with a resistance of 8 milliohms will show a voltage drop of 4V during this 500 A pulse test. When the battery control module 30 detects this drop of 4V, it will set a flag to indicate an issue with the contactor, and it will discontinue or limit fast charging of the traction battery 32. The flag may trigger an audio or visual alert. Otherwise, the battery control module 30 may continue with the fast charging.

The algorithms, methods, or processes disclosed herein can be deliverable to or implemented by a computer, controller, or processing device, which can include any dedicated electronic control unit or programmable electronic control unit. Similarly, the algorithms, methods, or processes can be stored as data and instructions executable by a computer or controller in many forms including, but not limited to, information permanently stored on non-writable storage media such as read only memory devices and information alterably stored on writeable storage media such as compact discs, random access memory devices, or other magnetic and optical media. The algorithms, methods, or processes can also be implemented in software executable objects. Alternatively, the algorithms, methods, or processes can be embodied in whole or in part using suitable hardware components, such as application specific integrated circuits, field-programmable gate arrays, state machines, or other hardware components or devices, or a combination of firmware, hardware, and software components.

While exemplary embodiments are described above, it is not intended that these embodiments describe all possible forms encompassed by the claims. The words used in the specification are words of description rather than limitation, and it is understood that various changes may be made without departing from the spirit and scope of these disclosed materials. The terms “controller” and “controllers,” for example, can be used interchangeably herein. Moreover, the functions associated with the battery control module 30 may be distributed among several controllers, which may be distributed throughout the vehicle 10.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle system comprising:
a controller programmed to, during DC fast charge of a traction battery, command a DC charge current to have a magnitude less than a predefined value and responsive to magnitudes of resulting voltage drop data for a fast charge contactor connected between a charge port and main contactor being less than a first threshold value, command the DC charge current to have a magnitude at a target high value and responsive to magnitudes of resulting voltage drop data for the fast charge contactor being greater than a second threshold value, discontinue the DC fast charge.

2. The vehicle system of claim 1, wherein the controller is further programmed to, responsive to the magnitudes being less than the second threshold value, continue the DC fast charge.

3. The vehicle system of claim 1, wherein the controller is further programmed to, prior to the DC fast charge, command the fast charge contactor open and responsive to magnitudes of the resulting voltage drop data being less than a second predefined value, preclude the DC fast charge.

4. The vehicle system of claim 1, wherein the controller is further programmed to, prior to the DC fast charge, command the fast charge contactor open and responsive to magnitudes of the resulting voltage drop data prior to the DC fast charge being greater than a second predefined value, command the fast charge contactor closed.

5. The vehicle system of claim 1, wherein the first threshold value and second threshold value are different.

6. The vehicle system of claim 1, wherein the second threshold value is a function of a magnitude of the target high value.

7. A method comprising:
during DC fast charge of a traction battery, commanding DC charge current to have a magnitude less than a predefined value and responsive to magnitudes of resulting voltage drop data for a fast charge contactor connected between a charge port and main contactor being less than a first threshold value, commanding the DC charge current to a target high value and responsive to magnitudes of resulting voltage drop data for the fast charge contactor being greater than a second threshold value, discontinue the DC fast charge.

8. The method of claim 7 further comprising, responsive to the magnitudes being less than the second threshold value, continuing the DC fast charge.

9. The method of claim 7 further comprising, prior to the DC fast charge, commanding the fast charge contactor open and responsive to magnitudes of the resulting voltage drop data being less than a second predefined value, precluding the DC fast charge.

10. The method of claim 7 further comprising, prior to the DC fast charge, commanding the fast charge contactor open and responsive to magnitudes of the resulting voltage drop data prior to the DC fast charge being greater than a second predefined value, commanding the DC fast charge contactor closed.

11. The method of claim 7, wherein the first threshold value and second threshold value are different.

12. The method of claim 7, wherein the second threshold value is a function of a magnitude of the target high value.

13. A vehicle comprising:
a power system including a traction battery, an electric machine, a main contactor connected between the traction battery and electric machine, a charge port, and a fast charge contactor connected between the main contactor and charge port; and
a controller programmed to, responsive to magnitudes of voltage drop data for the fast charge contactor being greater than a first predefined value, command the DC fast charge contactor closed, command a DC charge current to have a magnitude less than a second predefined value, and responsive to voltage drop data for the fast charge contactor resulting from the magnitude less than the second predefined value being less than a first threshold value, command the DC charge current to have a magnitude at a target high value.

14. The vehicle of claim 13, wherein the controller is further programmed to, responsive to magnitudes of voltage drop data for the fast charge contactor resulting from the target high value being greater than a second threshold value, discontinue the DC fast charge.

15. The vehicle of claim 13, wherein the controller is further programmed to, responsive to the magnitudes of the voltage drop data being less than the first predefined value, preclude closing of the DC fast charge contactor.

16. The vehicle system of claim 15, wherein the first threshold value and second threshold value are different.

17. The vehicle system of claim 15, wherein the second threshold value is a function of a magnitude of the target high value.
